(19) United States
(12) Patent Application Publication
(10) Pub. No.: US 2020/0135766 A1
(43) Pub. Date: Apr. 30, 2020

(54) MONOLITHIC INTEGRATION OF GAN HEMT AND SI CMOS

(71) Applicant: QUALCOMM Incorporated, San Diego, CA (US)

(72) Inventors: Ranadeep Dutta, Del Mar, CA (US); Sinan Goktepeli, San Diego, CA (US); Antonino Scuderi, San Diego, CA (US); George Pete Imthurn, San Diego, CA (US)

(21) Appl. No.: 16/175,691

(22) Filed: Oct. 30, 2018

(51) Int. Cl. H01L 27/12; H01L 29/04; H01L 29/778; H01L 29/45; H01L 29/423; H01L 29/47; H01L 21/8258; H01L 21/84; H01L 21/02; H01L 21/3065; H01L 29/40

(52) U.S. Cl. CPC H01L 27/1207; H01L 29/045; H01L 29/7787; H01L 29/454; H01L 29/42316; H01L 29/475; H01L 21/0262; H01L 21/84; H01L 21/02381; H01L 21/02458; H01L 21/0254; H01L 21/3065; H01L 29/401; H01L 21/8258

(57) ABSTRACT

A CMOS process is disclosed for manufacturing an integrated circuit including both MOSFETS and GaN HEMT devices. Each GaN HEMT device resides within an oxidized window that exposes a silicon substrate having a <111> crystal lattice orientation.

### TECHNICAL FIELD

This application relates to integrated circuits, and more particularly to the monolithic integration of GaN HEMT and Si CMOS.

### BACKGROUND

Complementary metal-oxide semiconductor (CMOS) technology is now quite mature such that digital circuits incorporating millions of transistors are readily integrated into ever-shrinking footprints on a silicon substrate. But mobile devices such as smartphones also require assorted radio frequency (RF) analog components such as power amplifiers and filters. III-V devices such as GaN high electron mobility transistors (HEMTs) offer superior RF performance for such RF analog components but are generally incompatible with CMOS processing. These non-CMOS analog components are thus typically fabricated individually and then integrated with the remaining system on a circuit board to complete the RF frontend (RFFE) of a smartphone or other wireless device. But the circuit board integration of such discrete components leads to substantial parasitic losses at higher frequencies such as in fifth-generation (5G) frequency bands. In addition, the fabrication of individual components and resulting circuit board integration increases manufacturing costs and complexity.

Accordingly, there is a need in the art for the monolithic integration of GaN HEMT with silicon CMOS.

### SUMMARY

Various integrated circuit are disclosed that include both silicon-based MOSFETs and GaN high electron mobility transistor (HEMT) devices that are formed using a CMOS process. In one embodiment, a silicon device layer for a silicon-on-insulator (SOI) wafer includes the silicon-based MOSFETs. The MOSFETS are insulated by shallow trench isolation (STI) regions. A window etched through one of the STI regions and through the buried oxide layer for the SOI wafer exposes a portion of the silicon handle substrate. In contrast to the <100> crystal lattice orientation for the silicon device layer, the silicon handle substrate has a <111> crystal lattice orientation. The <111> orientation provides reduced lattice mismatch to a GaN high electron mobility transistor (HEMT) epitaxially deposited onto the exposed portion of the silicon handle substrate to fill the window. A CMOS back-end-of-line (BEOL) process completes the integrate circuit. In some embodiments, the resulting integrated circuit is wafer bonded such as through a layer-transfer process to another silicon wafer containing additional MOSFETs.

In a non-SOI embodiment, a <111> silicon wafer is oxidized to include an oxidized layer. In contrast to the SOI embodiment, there is thus no silicon device layer for the non-SOI embodiment. But the CMOS manufacture process for the non-SOI embodiment is analogous in that a window for each GaN HEMT transistor is etched through the oxidized layer to expose a corresponding portion of the <111> silicon wafer. A GaN HEMT is epitaxially deposited to fill each window. A CMOS BEOL process completes processing of the <111> silicon wafer, which is then wafer bonded such as through a layer-transfer process to another silicon wafer containing MOSFETs.

These and other advantageous features may be better appreciated through the following detailed description.

### BRIEF DESCRIPTION OF THE DRAWINGS

FIG. 1 illustrates an integrated circuit formed using a silicon-on-insulator wafer patterned in a CMOS foundry to integrate CMOS MOSFETS and GaN HEMT devices into the integrated circuit in accordance with an aspect of the disclosure.

FIG. 2A illustrates the silicon-on-insulator (SOI) wafer for the manufacture of the integrated circuit of claim 1.

FIG. 2B illustrates the SOI wafer of FIG. 2A after the formation of CMOS MOSFETs but without any BEOL processing.

FIG. 2C illustrates the SOI wafer of FIG. 2B after the etching of a window to expose a portion of the silicon handle substrate.

FIG. 2D illustrates the SOI wafer of FIG. 2C after the deposition of epitaxial layers in the window onto the exposed portion of the silicon handle substrate.

FIG. 2E illustrates the SOI wafer of FIG. 2D after the deposition of the source/drain contacts and the gate to complete the formation of the GaN HEMT.

FIG. 3 illustrates a first silicon substrate patterned with GaN HEMT devices using a CMOS process wherein the first silicon substrate is wafer bonded to a second silicon wafer containing CMOS MOSFETs in accordance with an aspect of the disclosure.

FIG. 4 illustrates the silicon-on-insulator wafer of FIG. 1 wafer bonded to another silicon wafer containing CMOS MOSFETs in accordance with an aspect of the disclosure.

FIG. 5 is a flowchart for a method of manufacturing an integrated circuit including both silicon-based MOSFETs and GaN HEMTs using a CMOS process in accordance with an aspect of the disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION

At least one GaN HEMT is monolithically integrated onto a silicon-on-insulator (SOI) substrate. The SOI substrate may include CMOS metal-oxide field effect transistors (MOSFET). In this fashion, low cost and mature CMOS processing technology is leveraged to produce an integrated circuit containing both Si CMOS and GaN HEMT devices. Turning now to the drawings, an example integrated circuit 100 is formed on a silicon-on-insulator (SOI) wafer 101. But in contrast to conventional CMOS SOI architectures, a silicon handle substrate 105 for wafer 101 has a <111> crystal lattice orientation as opposed to a <100> orientation. As will be explained further herein, such a crystal lattice orientation presents a minimal lattice mismatch to a GaN HEMT 110 integrated onto wafer 101. Silicon-on-insulator wafer 101 is a 300 mm wafer in the following description although it will be appreciated that the wafer size may vary in alternative embodiments.

SOI substrate 101 includes a buried oxide (BOX) layer 140 that insulates silicon handle substrate 105 from a device silicon layer 160 having a conventional <100> crystal lattice orientation. Device silicon layer 160 is patterned and doped to form a plurality of CMOS-process MOSFETs 145 that are isolated by shallow trench isolation (STI) regions 165. As illustrated, MOSFETS 145 are n-type metal-oxide semiconductor (NMOS) MOSFETs but it will be appreciated that device silicon layer 160 may readily be patterned and doped to also support p-type metal-oxide semiconductor (PMOS) devices as well. A window 180 through device layer 160 and box layer 140 is filled by a GaN HEMT 110 device. STI regions 165 border window 180 so that GaN HEMT 110 is isolated from MOSFETs 145. It will be appreciated that SOI wafer 101 may include a plurality of such windows 180 to support a corresponding plurality of GaN HEMT devices. GaN HEMT 110 includes an aluminum nitride (AlN) nucleation layer 115 contacting an exposed portion of silicon handle substrate 105 within window 180. Nucleation layer 115 is separated from a gallium nitride (GaN) channel 125 by a graded aluminum gallium nitride (AlGaN) buffer layer 120. An AlGaN barrier layer 130 separates GaN channel 125 from a GaN cap layer 135. Source/drain contacts 185 and a gate 190 contact GaN cap layer 135. Note that it would be conventional in a III-V process to form source/drain contacts 185 and gate 190 using gold. But such III-V gold processing steps are not compatible with the CMOS process used to construct integrated circuit 100. Suitable CMOS-compatible contact materials are aluminum based. For example, gate 190 may be formed using nickel aluminum tantalum (NiAlTa) whereas contacts 185 may be formed of titanium aluminum tantalum (TiAlTa).

A conventional back-end-of the-line (BEOL) process may be used to complete integrated circuit 100. For illustration clarity, integrated circuit 100 is shown having just a first metal layer M1 and a second metal layer M2 as insulated by corresponding dielectric layers 175 but it will be appreciated that additional metal layers may be implemented in integrated circuit 100 using conventional BEOL processes. MOSFETs 145 are coupled to GaN HEMT 110 through vias 150 extending through the dielectric layers to leads formed in the metal layers. Integrated circuit 100 connects to additional integrated circuits or other remote devices through terminals (not illustrated) such as copper pillars or solder balls. Integrated circuit 100 may be advantageously constructed in a CMOS fabrication facility or foundry without requiring any separate processing by a III-V foundry. Suitable applications such as the RF frontend of a smartphone may thus be constructed using integrated circuit 100 as opposed to the conventional use of multiple integrated circuits, which significantly lowers cost and complexity. Moreover, the RF performance and fidelity are greatly enhanced as the parasitic resistance, capacitance, and inductance for the signal coupling between MOSFETs 145 and GaN HEMT 110 in integrated circuit 100 are advantageously lowered as compared to the parasitic resistance, capacitance, and inductance introduced by the circuit board coupling of discrete integrated circuits. A CMOS-compatible method of manufacturing integrated circuit 100 will now be discussed.

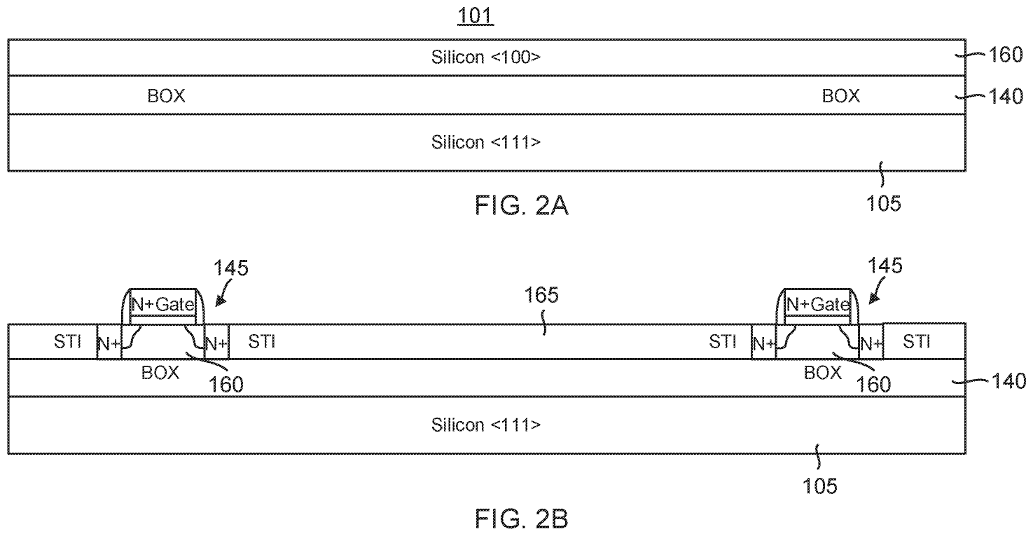

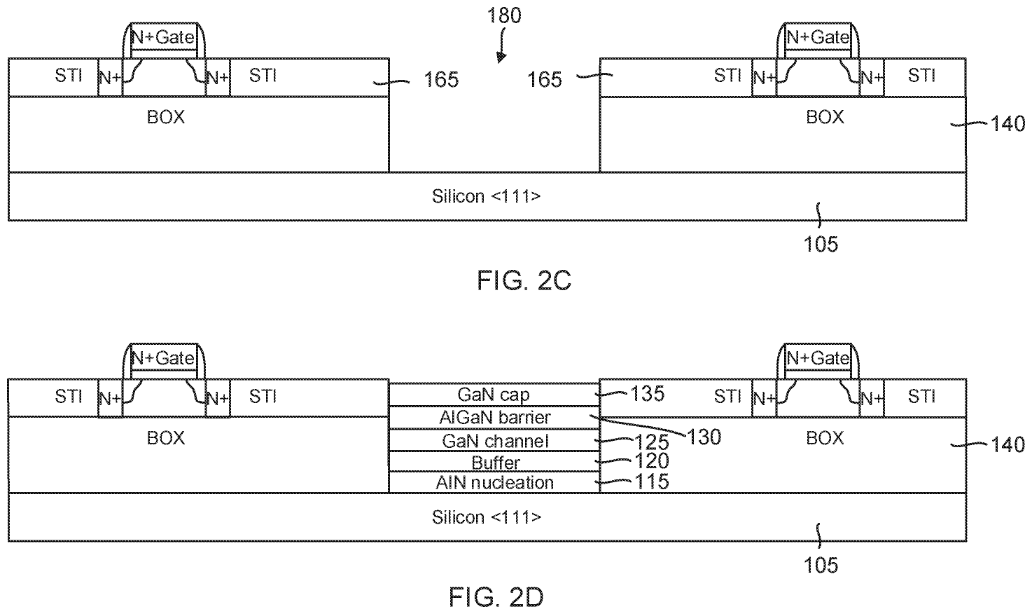

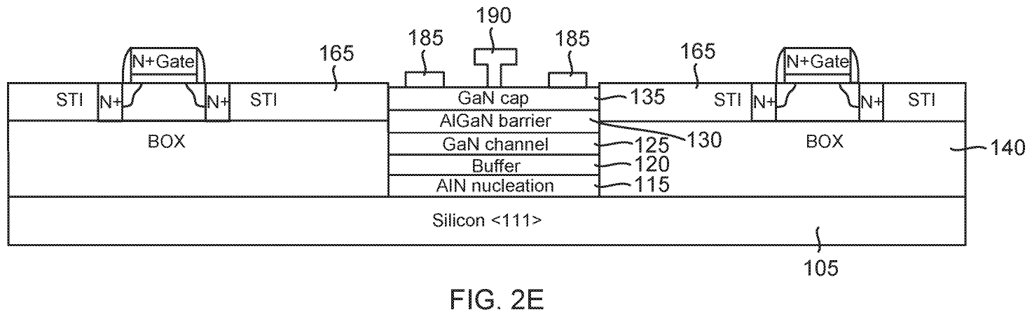

The manufacture begins with a silicon-on-insulator (SOI) substrate or wafer 101 as shown in FIG. 2A. At this stage, silicon device layer 160 is un-patterned and thus exists as a continuous layer across buried oxide layer 140. As noted earlier, the crystal lattice orientation of silicon handle substrate 105 is <111> whereas the crystal lattice orientation of device layer 160 is <100>. The CMOS foundry then patterns device layer 160 such as through conventional CMOS processing steps to form CMOS transistors 145 and shallow trench isolation regions 165 as shown in FIG. 2B. Although CMOS transistors 145 are planar transistors, it will be appreciated that non-planar CMOS processes such as that used in a fin-shaped field-effect transistor (FinFET) process may be used to pattern device layer 160 to form non-planar CMOS transistors in alternative embodiments. Patterning of device layer 160 includes other conventional CMOS front-end steps such as silicidation and a subsequent deposition of inter-layer dielectric (ILD) and silicon nitride (Si₃N₄) (not illustrated).

To begin the formation of a GaN high electron mobility transistor, a window 180 is etched through one of the shallow trench isolation regions 165 and through buried oxide layer 140 to expose silicon handle layer 105 as shown in FIG. 2C. Note that the sidewalls of window 180 are formed with exposed portions of buried oxide layer 140 and shallow trench isolation region 165 as opposed to having any exposure of silicon device layer 160. In this fashion, a GaN high electron mobility transistor may be deposited within window 180 without needing any further isolation from MOSFETs 145. Although etching of window 180 occurs through a single shallow trench isolation region 165 in FIG. 2C, it will be appreciated that window 180 may instead be etched through a pair of shallow trench isolation regions that are separated by an un-patterned portion of silicon device layer 160 as such an etching will still result in the isolation of window 180 from silicon device layer 160. The etching of window 180 thus occurs through at least one shallow trench isolation region 165. Suitable techniques to etch window 180 include reactive ion etching or other etching techniques that are selective to the etching of oxidized silicon such as buried oxide layer 140 and shallow trench isolation region 165 as opposed to silicon handle layer 105. As known in the semiconductor arts, etching of window 180 includes the deposition and patterning of one or more mask layers (not illustrated).

With window 180 completed, the CMOS foundry may proceed to epitaxially deposit layers for GaN HEMT 110 within window 180 as shown in FIG. 2D. Suitable selective epitaxial techniques include molecular beam epitaxy or metalorganic chemical vapor deposition (MOCVD). To reduce stress and lattice mismatch, deposition begins with the formation of a relatively thin AlN nucleation layer 115 onto the exposed silicon handle substrate 105 within window 180. Nucleation layer 115 is then covered with a graded AlGaN buffer layer 120. Buffer layer 120 functions to ensure channel pinch-off and current saturation as well as to lower loss and cross-talk. Deposition continues with the formation of a GaN channel layer 125 followed by the deposition of a AlGaN barrier layer 130. Barrier layer 130 has a larger bandgap than a bandgap for GaN channel layer 125. In general, the bandgap is a function of aluminum concentration in barrier layer 130. Suitable aluminum concentrations include 20 to 30% for barrier layer 130. In alternative embodiments, barrier layer 130 may comprise lattice-matched indium aluminum nitride (In_{0.17}Al_{0.83}N) instead of AlGaN. To prevent oxidation and provide lower resistivity, barrier layer 130 is covered by a relatively-thin GaN cap layer 135 to complete the epitaxial deposition.

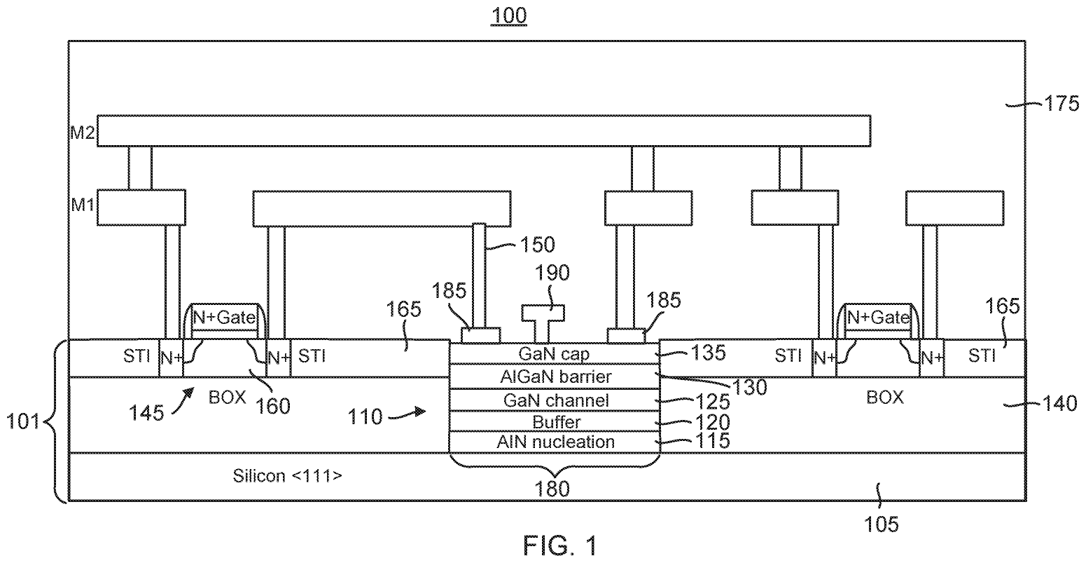

To complete GaN HEMT 110, source/drain contacts 185 and gate 190 are deposited as shown in FIG. 2E. Note that the conventional use of gold such as practiced in III-V foundries to form the GaN HEMT contacts is incompatible with CMOS processes. Thus, both source/drain contacts 185 and gate 190 are both aluminum-based. For example, source/drain contacts 185 may comprise titanium aluminum tantalum (TiAlTa) whereas gate 190 may comprise nickel aluminum tantalum (NiAlTa). To lower resistance at higher frequencies, gate 190 may be T-shaped such as formed through deposition onto patterned silicon nitride layers (not illustrated). Conventional silicon nitride passivation and back-end-of-line (BEOL) CMOS processing may proceed to complete integrated circuit 100 as discussed with reference to FIG. 1. Note that the formation order for CMOS transistors 145 and GaN HEMT 110 may be reversed in alternative embodiments. Referring again to FIG. 2A, window 180 would thus be etched and GaN HEMT 110 deposited before the formation of CMOS transistors 145 in such embodiments.

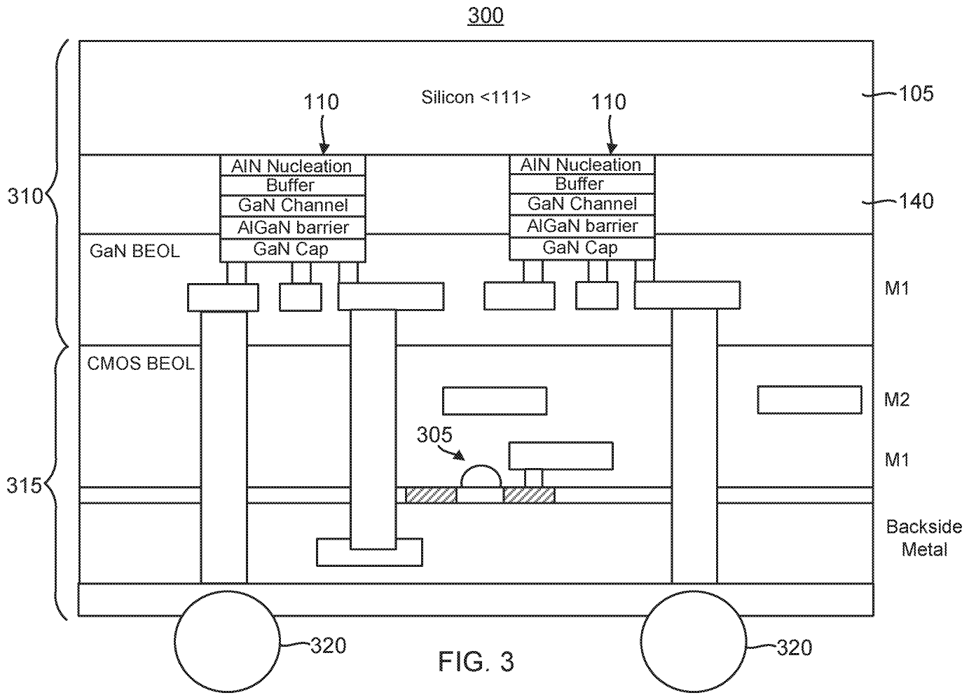

In an alternative embodiment, the processing steps discussed with regard to FIGS. 2A through 2E may be modified to eliminate the formation of CMOS devices such as MOSFETS 145. There is thus no silicon device layer so that such alternative embodiments are denoted herein as non-SOI embodiments. In the non-SOI embodiments, oxidized layer 140 is deposited on silicon substrate 105 as shown in FIG. 3 for an integrated circuit 300. In alternative embodiments, a thermal process or a combination of a thermal process and oxide deposition may be used to form oxidized layer 140. Windows are then etched in oxidized layer 140 to expose silicon substrate 105 (which retains its <111> orientation) and an AlN nucleation layer, buffer layer, GaN channel, barrier layer, and cap layer epitaxially deposited in the windows to form the bulk of each GaN HEMT device 110. In general, there is a one-to-one correspondence between each window and the corresponding GaN HEMT device 110. After deposition of the gates and source/drain contacts to complete the GaN HEMT devices 110, a CMOS BEOL process completes a GaN-HEMT-containing wafer 310. Another silicon wafer 315, which may be bulk silicon or a silicon-on-insulator wafer, is processed to include CMOS MOSFETs (for illustration clarity, only a single CMOS MOSFET 305 is illustrated in FIG. 3). After a BEOL process to form metal layers such as metal layers M1 and M2 and associated vias and contacts, silicon wafer 315 is wafer bonded such as through a layer-transfer process to the GaN-HEMT-containing wafer 310. To provide contacts to integrated circuit 300, a backside metal layer is added to silicon wafer 315 to support terminals such as copper pillars or solder balls 320. For illustration clarity, wafer 310 is shown having just a single metal layer M1 but it will be appreciated that a plurality of metal layers may be implemented in alternative embodiments. Regardless of the number of metal layers, each of wafers 310 and 315 will have an uppermost metal layer that connects through contacts formed during the layer-transfer and wafer-bonding process to the uppermost metal layer in the adjoining wafer. As known in the CMOS BEOL arts, the various metal layers are patterned into the appropriate leads and coupled together through corresponding vias to support the desired communication between GaN HEMTs 110 and MOSFETs 305.

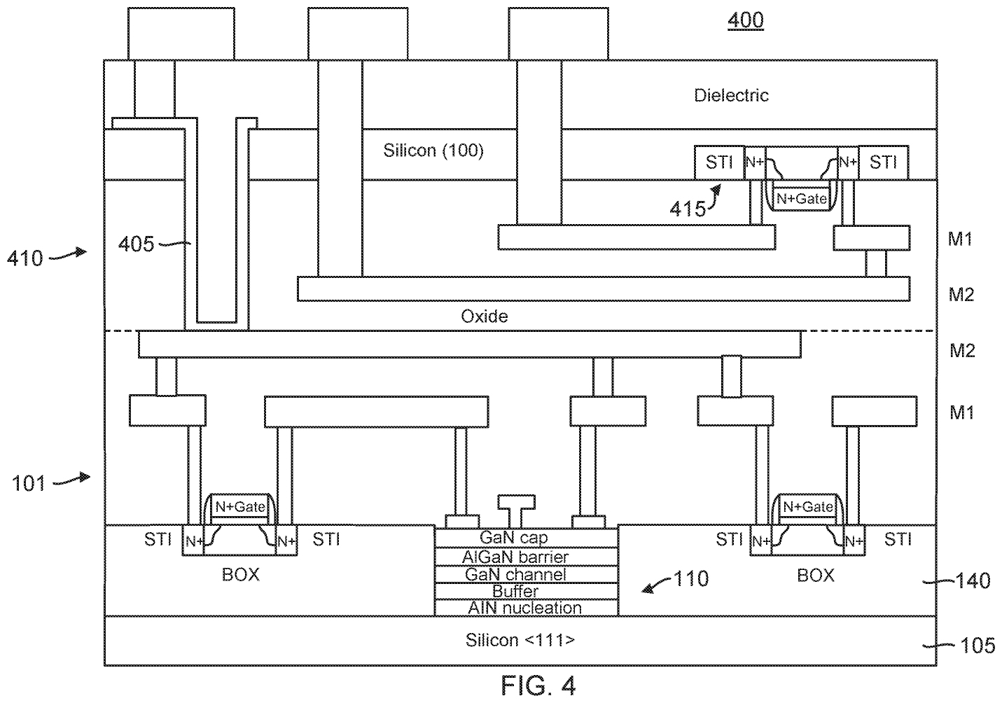

Wafer 101 as discussed with reference to FIG. 1 may also be wafer bonded such as through a layer transfer process to another silicon wafer to form a wafer-bonded integrated circuit 400 as shown in FIG. 4. In particular, a <100> silicon wafer 410 is patterned with MOSFETs 415 (for illustration clarity, only a single MOSFET 415 is shown in FIG. 4). A BEOL process forms the metal layers such as metal layers M1 and M2 and the corresponding dielectric layers and vias. In the layer-transfer process, contacts to the uppermost metal layer for each of wafers 101 and 410 are coupled together. To assist the electrical coupling between the wafers, vias for wafer 410 that couple to wafer 101 may be lined with an electrically conductive liner 405. Contacts for wafer-bonded integrated circuit 400 are on the backside of wafer 410 that couple through through-substrate vias in the silicon substrate for wafer 410 to the metal layers for wafer 101. A dielectric layer insulates the backside contacts from the silicon substrate for wafer 410.

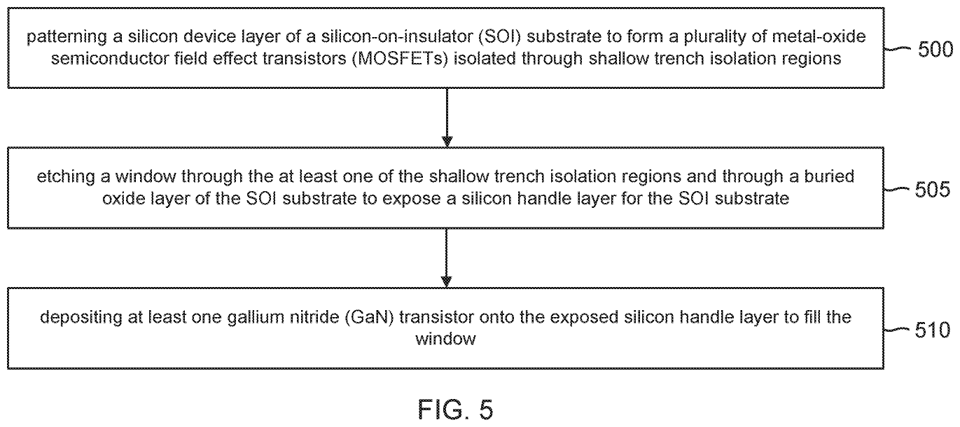

A method of manufacturing an integrated circuit having both CMOS devices and GaN HEMT devices using a CMOS process will now be discussed with reference to the flowchart of FIG. 5. The method includes an act 500 of patterning a silicon device layer of a silicon-on-insulator (SOI) substrate to form a plurality of metal-oxide semiconductor field effect transistors (MOSFETs) isolated through shallow trench isolation regions. The patterning of MOSFETs 145 and formation of STI regions 165 as discussed with reference to FIG. 1 and FIG. 2B is an example of act 500. The method further includes an act 505 of etching a window through the at least one of the shallow trench isolation regions and through a buried oxide layer of the SOI substrate to expose a silicon handle layer for the SOI substrate. The etching of window 180 as discussed with regard to FIG. 2C is an example of act 505. Finally, the method includes an act 510 of depositing at least one gallium nitride (GaN) transistor onto the exposed silicon handle layer to fill the window. The epitaxial deposition of the GaN transistor layers as discussed with regard to FIG. 2D is an example of act 510.

It will be appreciated that many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

1-9. (canceled)

10. An integrated circuit, comprising:
a silicon handle substrate having a <111> crystal lattice orientation;
a silicon device layer configured to include a plurality of metal-oxide field effect transistors (MOSFETs);
a buried oxide layer separating the silicon handle substrate from the silicon device layer;
a plurality of shallow trench isolation (STI regions configured to isolate the plurality of MOSFETs, wherein one of the STI regions includes a window extending through the buried oxide layer to the silicon handle substrate;
a gallium nitride high electron mobility transistor (GaN HEMT) within the window comprising:
a pair of aluminum-based source/drain contacts;
an aluminum-based gate;
a nucleation layer contacting the silicon handle substrate;
a buffer layer contacting the nucleation layer;
a gallium nitride (GaN) channel layer contacting the buffer layer;
a barrier layer contacting the GaN channel layer; and
a cap layer contacting the barrier layer, wherein the pair of aluminum-based source/drain contacts and the aluminum-based gate are all coupled to the GaN HEMT through the cap layer.

11. (canceled)

12. The integrated circuit of claim 10, wherein the pair of aluminum-based source/drain contacts comprise a pair of titanium aluminum tantalum (TiAlTa) source/drain contacts.

13. The integrated circuit of claim 10, wherein the aluminum-based gate comprises a T-shaped nickel aluminum tantalum (NiAlTa) gate.

14. (canceled)

15. The integrated circuit of claim 10, wherein the nucleation layer comprises aluminum nitride (AlN).

16. The integrated circuit of claim 10, wherein the buffer layer comprises aluminum gallium nitride (AlGaN).

17. The integrated circuit of claim 10, wherein the barrier layer comprises AlGaN.

18. The integrated circuit of claim 10, wherein the barrier layer comprises lattice-matched indium aluminum nitride (InAlN).

19. The integrated circuit of claim 10, wherein the cap layer comprises GaN.

20. The integrated circuit of claim 10, further comprising:
an additional integrated circuit wafer bonded to the integrated circuit, wherein the additional integrated circuit includes an additional plurality of MOSFETs.

21-27. (canceled)
